(19) United States
(12) Patent Application Publication
(10) Pub. No.: US 2003/0160638 A1
(43) Pub. Date: Aug. 28, 2003

(54) Transistor driving circuit

(76) Inventor: Fumihiko Hirose, Yokohama (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/082,105

(22) Filed: Feb. 26, 2002

(51) Int. Cl. H03B 1/00

(52) U.S. Cl. 327/108

(57) ABSTRACT

A transistor driving circuit of the invention comprises a first transistor connected to a circuit including a load and a power supply, a second transistor which has an emitter connected to a base of the first transistor and has a collector connected to a first bias having a lower voltage, and a third transistor which has an emitter connected to the base of the first transistor and has a collector connected to a second bias whose voltage is set higher than the voltage of the first bias, wherein the second and third transistors inject a current to the base of the first transistor so as to raise the first transistor.

### BACKGROUND OF THE INVENTION

1. Field of the Invention

The invention relates to a transistor driving circuit which is used as a power electronics circuit and uses a bipolar transistor as a switch device.

2. Description of the Related Art

There is a keen demand for energy saving from users on inverters of an air conditioner, an electric vehicle or the like. For an inverter circuit to make effective use of input power, it is regarded as important to reduce a loss of power so as to increase energy conversion efficiency. For example, the reduction of power loss of a motor driving circuit leads to size reduction of a radiating fin, and this is important for size reduction and cost reduction of the electrical equipment.

In a switching circuit using a conventional bipolar transistor as a switch device, a driving circuit of the transistor comprises a transistor 5 (TR1) and a low-power transistor 9 (TR2) whose emitter is connected to a base of the transistor 5 (TR1), as shown in FIG. 3. A bias Vcc which sets a voltage is connected to a collector of the low-power transistor 9 (TR2) through resistance R so that the transistor 9 (TR2) supplies a base current to the transistor 5 (TR1) so as to switch-on the transistor 5 (TR1).

The resistance R functions to control the base current of the TR1 when the TR1 is on. The resistance R can prevent an excess current injection to the base of the TR1 at the on-state condition. In this example, the resistance R is connected to the collector of the pre-transistor 9, but instead, the resistance R may be interposed between the emitter of the pre-transistor 9 and the base of the TR1. In such a driving circuit, a delay occurs in the rise of a collector current of the TR2 even when a signal is applied through a signal input terminal due to wiring inductance incident to the circuit between the collector of the TR2 and the bias Vcc between the base of the TR1 and the emitter of the TR2. Provided that the wiring inductance is L, the delay time is proportional to the inductance L and the resistance R and is inversely proportional to the bias Vcc. A voltage of the bias Vcc is set as high as possible in order to avoid the delay time. Depending on the required switching time, the value of the bias Vcc is often set to 10 V or higher to turn on the TR1 within 1 μs, for example. Setting the bias Vcc to a higher voltage yields shorter switching time and thus quicker operation, but this causes a problem, that is, an increase in a collector-emitter power dissipation of the TR2 and a power dissipation of the resistance R connected to the collector. Therefore, high-speed operation causes heat radiations of the transistor TR2 and the resistance R.

One approach for avoiding the problem mentioned above is that a resistance and a capacitor are connected in parallel as shown in FIG. 4. This circuit functions in about the same manner as the above-mentioned circuit even through the adoption of connection shown in FIG. 5. In the circuit, the capacitor has impedance which closely approximates zero at turn-on. Therefore, the rise of the collector current of the TR2 is very high, and after a lapse of a given time, the impedance of the capacitor increases, so that the collector current of the TR2 is limited by the resistance R. In the circuit, even when the resistance R is increased, the capacitor allows reducing the delay time at the rise of the collector current of the TR2, namely, the base current of the TR1, at turn-on. The capacitor is often called a speedup capacitor.

However, the circuit also has a problem. More specifically, when the bias Vcc is reduced in order to reduce the loss of the resistance, the wiring inductance causes a reduction of the delay time. Therefore, the bias Vcc must be set to a somewhat higher value, and actually, the bias Vcc needs 10 V or higher in order that the rise time of the transistor TR1 may be lower than 1 μs.

In the conventional driving circuits shown in FIGS. 4 and 5, when a set voltage value of the bias Vcc is reduced, the wiring inductance causes a delay in the rise of the base current of the transistor 5 (TR1) at turn-on and thus results in an increase in switching loss of the transistor 5 (TR1). Therefore, the conventional driving circuits are limited in reducing the set voltage value of the bias Vcc. In addition, a problem exists: a higher bias Vcc causes an increase in power-losses of the preceding transistor and the resistance connected to the transistor, that is, a loss of the driving circuit, and thus causes the circuit to generate heat.

### BRIEF SUMMARY OF THE INVENTION

It is an object of the invention to provide a transistor driving circuit which allows a base current to rise quickly, causes less switching power-loss at turn-on and causes less power-loss of the driving circuit.

A transistor driving circuit of the invention comprises: a first transistor TR1 connected to a circuit including a load and a power supply; a second transistor TR2 which has an emitter connected to a base of the first transistor TR1 and has a collector connected through resistance or directly to a first bias Vcc1 having a lower voltage; and a third transistor TR3 which has an emitter connected to the base of the first transistor TR1 and has a collector connected to a second bias Vcc2 whose voltage is set higher than the voltage of the first bias Vcc1, wherein the second and third transistors TR2 and TR3 inject a current the base of the first transistor TR1 so as to raise the first transistor TR1.

Preferably, the transistor driving circuit further comprises a capacitor which is interposed in a base current feeder circuit of the third transistor TR3 so as to feed a current through a base of the third transistor TR3 only in a short time at turn-on.

Not only a bipolar transistor but also a metal-oxide-semiconductor field effect transistor (MOSFET) may be used as each of the pre-transistors TR2 and TR3. In this case, the emitter, the base and the collector may correspond to a source, a gate and a drain, respectively.

The correlation between switching time and base drive conditions is as follows.

If an off state in which a negative voltage is applied to a signal input terminal shown in FIG. 1 is changed to an on state by the input of a positive voltage and thereafter the on state is changed to the off state through the input of a negative voltage, an output waveform becomes delayed and deformed as compared to an input waveform.

The output waveform is defined as four switching times, that is, a delay time td, a rise time tr, a store time ts and a fall time tf. The delay time td and the rise time tr are associated with ON operation of the transistor. On the other hand, the store time ts and the fall time tf are associated with OFF operation of the transistor. In the switch-on, the ON time is equal to the sum total of the delay time td and the rise time tr, (td+tr).

Herein, “the delay time td” refers to the time which elapses from the input of a pulse until the output waveform reaches 10% of the maximum amplitude. The delay time td is generally negligible because the delay time td is very short.

“The rise time tr” refers to the time which elapses until the output waveform reaches 10% to 90% of the maximum amplitude. The rise time tr corresponds to the time required for supplying electric charge to make a carrier injection in a base region in order to feed a collector current. The rise time tr can be reduced by forcedly feeding a base current (i.e., the apply of an input waveform). More specifically, the base current rises quickly through feeding of a large base current only at the instant of turn-on.

In the driving circuit of the invention, the collector of the second transistor TR2 is set to a lower voltage, the collector of the third transistor TR3 is set to a higher voltage, and the second and third transistors TR2 and TR3 each having a smaller capability to pass a current into the base of the power transistor TR1. Therefore, they reduce the ON time (td+tr) required for the rise of the base current of the power transistor TR1, so that the base current rises quickly.

The description is now given with reference to a comparative example shown in FIG. 4 with regard to the effect of reducing a loss of the driving circuit of the invention shown in FIG. 1. In the circuit shown in FIG. 1, the total P1 of power-losses is given by the following equation (1):

P1=Vcc2²/R2×T2+Vcc1*Ib×T1 (1)

where T1 and T2 denote the times when the TR2 and TR3 are on, respectively, P1 denotes the power-loss of the driving circuit, that is, the total of power-losses of the TR2 and TR3 and R1 and R2, and Ib denotes a steady-state base current of the power transistor TR1 at turn-on. The steady-state base current is supplied to the base of the power transistor TR1 through the second transistor TR2. Since the time when the third transistor TR3 is on is limited to a very short time by the capacitor connected to the base of the third transistor TR3, the first term of the above equation (1) can be ignored, and therefore the total of power-losses, P1 is expressed as the following equation (2) into which the above equation (1) is changed.

P1=Vcc1*Ib×T1 (2)

On the other hand, a power-loss of a circuit shown in FIG. 4 is as follows. A loss P2 is given by the following equation (3):

P2=Vcc2*IB*T1 (3)

where T1 denotes the time when the second transistor TR2 is on, and P2 denotes the power-loss of the driving circuit, that is, the power-loss of a fourth transistor TR4 and resistance R3.

In the circuit shown in FIG. 1, the effect of the invention can reduce Vcc1 to a value as low as 10 V or less but cannot reduce Vcc2. As can be seen from the above equations (2) and (3), the total of power-losses, P1 is smaller than the power-loss P2 (P1<P2), and therefore the circuit of the invention can also reduce the power-loss of the driving circuit.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiment of the invention, and together with the general description given above and the detailed description of the embodiment given below, serve to explain the principles of the invention.

FIG. 1 is a drawing showing a transistor driving circuit according to an embodiment of the invention;

FIGS. 2A and 2B are current waveforms showing the characteristics of switching operation of the circuit of the invention and the characteristics of switching operation of a circuit of the prior art, respectively;

FIG. 3 is a drawing showing a transistor driving circuit of the prior art;

FIG. 4 is a drawing showing a transistor driving circuit of a comparative example; and

FIG. 5 is a drawing showing a transistor driving circuit of a comparative example.

### DETAILED DESCRIPTION OF THE INVENTION

A preferred embodiment of the invention will be described below with reference to the accompanying drawings.

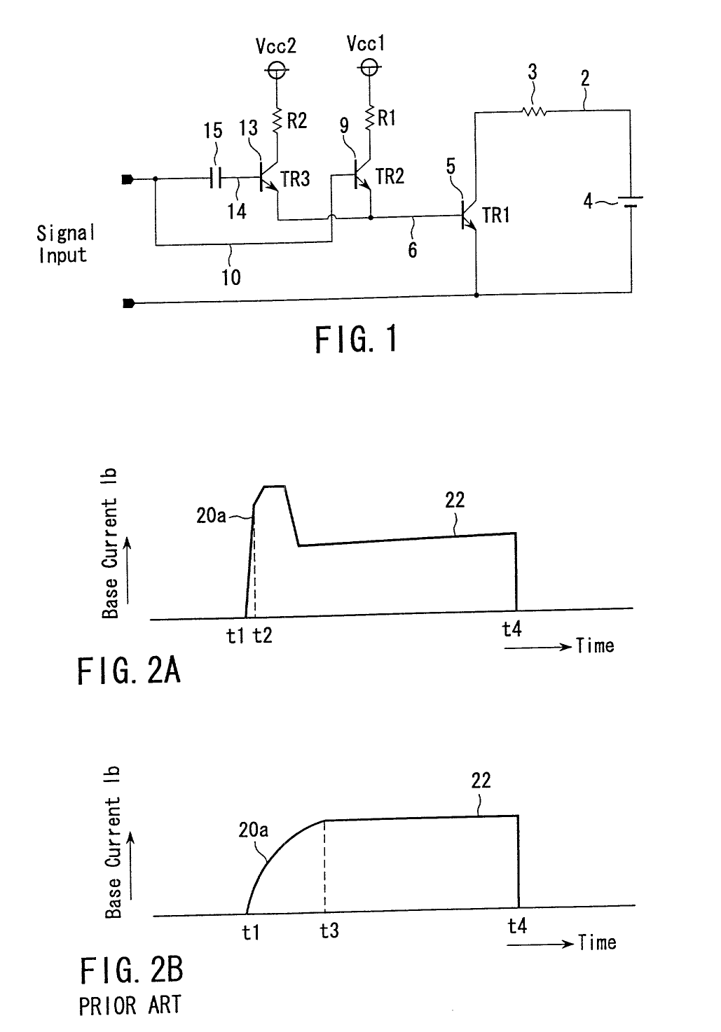

As shown in FIG. 1, a transistor driving circuit according to the embodiment of the invention comprises a signal input terminal having a circuit 2 including a load 3, a power supply 4 and a first transistor 5 (TR1). Emitters of second and third transistors 9 and 13 (TR2 and TR3) are connected to a base of the first transistor 5 (TR1) of the circuit. A power transistor having a large collector-emitter power dissipation is used as the first transistor 5 (TR1), and a general-purpose transistor having a smaller collector-emitter power dissipation than the dissipation of the first transistor 5 (TR1) is used as each of the second and third transistors 9 and 13 (TR2 and TR3).

In the embodiment, the first transistor 5 (TR1) is set to, for example, 150 V and 20 A, and each of the second and third transistors 9 and 13 (TR2 and TR3) is set to, for example, 50 V and 10 A.

A first bias Vcc1 which sets a voltage is connected to a collector of the second transistor 9 (TR2), and a second bias Vcc2 which sets a voltage is connected to a collector of the third transistor 13 (TR3). A set voltage value of the first bias Vcc1 is set lower than that of the second bias Vcc2. For instance, the voltage of the first bias Vcc1 is set to 2 V, and the voltage of the second bias Vcc2 is set to 10 V.

Furthermore, a capacitor 15 is interposed in a base current feeder circuit of the third transistor 13 (TR3). The capacitor 15 has a capacitance to feed a current through a base of the third transistor 13 (TR3) only in a short time at turn-on.

Next, switching operation will be described with reference to FIGS. 2A and 2B.

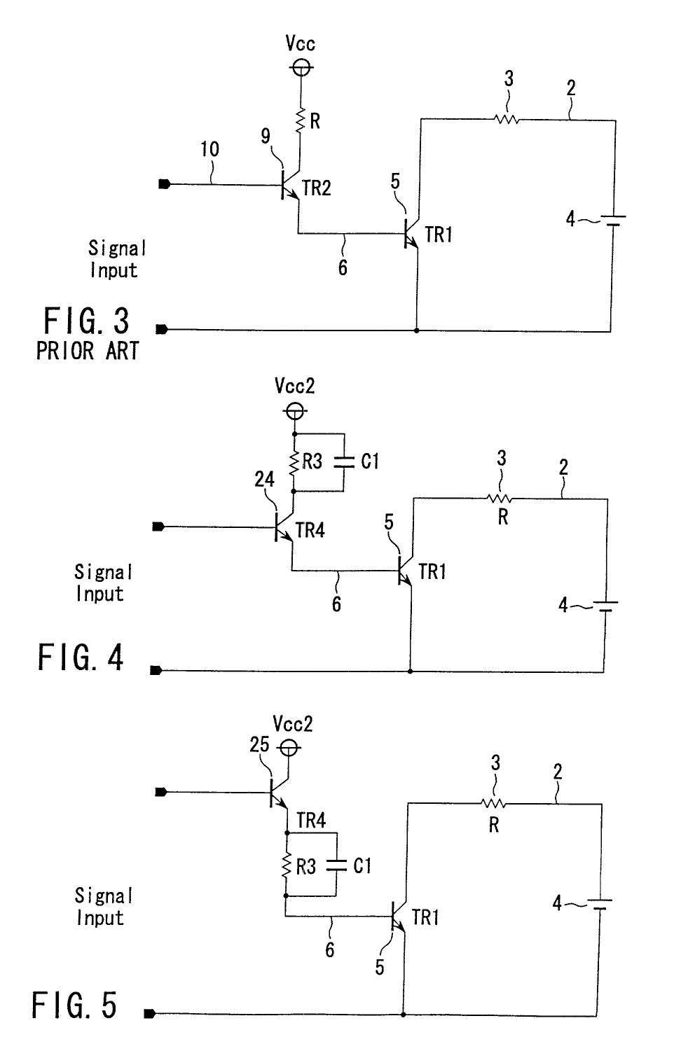

FIGS. 2A and 2B are current waveforms showing the characteristics of switching operation of the circuit of the invention and the characteristics of switching operation of the circuit of the prior art shown in FIG. 3, respectively, wherein the horizontal axis indicates the time and the vertical axis indicates a base current Ib.

The driving circuit of the invention is configured in the following manner. As is apparent from a current waveform shown in FIG. 2A, the set voltage value of the first bias Vcc1 is set lower so as to reduce a loss of the second transistor TR2, and the second and third transistors TR2 and TR3 each having a smaller capability injecting a current to pass through the base of the power transistor TR1. Therefore, this reduces the ON time t1 to t2 required for the rise of the base current Ib of the power transistor TR1, so that the base current Ib rises quickly.

The driving circuit of the prior art is configured in the following manner. As is apparent from a current waveform shown in FIG. 2B, the ON time t1 to t3 required for the rise of the base current Ib of the power transistor TR1 is longer than the above-mentioned ON time t1 to t2. Incidentally, the ON time t1 to t3 of the circuit of the prior art is from 1 μs to 2 μs inclusive, whereas the ON time t1 to t2 of the circuit of the invention is 100 ns.

The description is now given with regard to a power-loss of the driving circuit of the embodiment, that is, a power-loss of a part preceding the power transistor TR1. In the circuit of the embodiment, resistance R1 is set to 0.5Ω, resistance R2 is set to 5Ω, and the capacitor 15 is set to 0.01 μF. A steady-state current of the TR1 which is a switching transistor is set to 2 A at turn-on. A signal of a single square wave, which requires 1 sec for the ON time, is applied to the signal input terminal. In this case, the power-loss of the driving circuit is about 4 J.

In the circuit of a comparative example shown in FIG. 4, resistance R3 is set to 5Ω, and a capacitor C1 is set to 0.1 μF. A steady-state current of the TR1 which is a switching transistor is set to 2 A at turn-on. A signal of a single square wave, which requires 1 sec for the ON time, is applied to the signal input terminal. In this case, the power-loss of the driving circuit is about 20 J.

As a result, the use of the invention permits greatly reducing the power-loss of the driving circuit and also allows reducing the ON time to 1 μs or less.

According to the invention, the power-loss of the driving circuit can be reduced because the set voltage value of the bias Vcc1 is set lower. Moreover, the second and third transistors TR2 and TR3 inject a current to the base of the first transistor TR1, and therefore this greatly reduces the ON time required for the rise of the base current of the first transistor TR1, so that switching power-loss of the TR1 can be reduced. More specifically, power-loss reduction of the whole circuit can be accomplished because the set voltage value of the bias Vcc1 can be set lower without fear of a delay in the rise of the base current of the first transistor TR1.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A transistor driving circuit comprising:
a first transistor TR1 connected to a circuit including a load and a power supply;
a second transistor TR2 which has an emitter or a source connected to a base of said first transistor TR1 and has a collector or a drain connected through resistance or directly to a first bias Vcc1 having a lower voltage; and
a third transistor TR3 which has an emitter or a source connected to the base of said first transistor TR1 and has a collector or a drain connected through resistance or directly to a second bias Vcc2 whose voltage is set higher than the voltage of said first bias Vcc1,
wherein said second and third transistors TR2 and TR3 inject a current to the base of said first transistor TR1 so as to raise said first transistor TR1.

2. The transistor driving circuit according to claim 1, further comprising a capacitor which is interposed in a base current feeder circuit of said third transistor TR3 so as to feed a current through a base of said third transistor TR3 only in a short time at turn-on.

3. The transistor driving circuit according to claim 1, wherein a collector-emitter power dissipation of said first transistor TR1 is larger than that of each of said second and third transistors TR2 and TR3.
